(19) United States
(12) Patent Application Publication
(10) Pub. No.: US 2025/0259871 A1
(43) Pub. Date: Aug. 14, 2025

(54) TRAY FOR LARGE-SIZE SEMICONDUCTOR INTEGRATED CIRCUITS

(71) Applicant: SHINON CORPORATION, Tokyo (JP)

(72) Inventor: Zhang Liang, Tokyo (JP)

(73) Assignee: SHINON CORPORATION, Tokyo (JP)

(21) Appl. No.: 19/053,918

(22) Filed: Feb. 14, 2025

(30) Foreign Application Priority Data
Feb. 14, 2024 (JP) JP2024-020247

(51) Int. Cl. H01L 21/673; B65D 1/36; B65D 85/30

(52) U.S. Cl. CPC H01L 21/67333; B65D 1/36; B65D 85/30

(57) ABSTRACT

A tray 1 for large-size semiconductor integrated circuits comprises one or a plurality of pockets 2 for accommodating large-size semiconductor integrated circuits is provided. On the inner bottom surface 4 of each of the pockets, a rounded recess 10 having a circular outline 8 is formed. The circular outline 8 is generally concentric with the center of each of the pockets. The rounded recess 10 formed on the inner bottom surface 4 of a pocket 2 prevents the inner bottom surface 4 from contacting terminals on the bottom face of a semiconductor integrated circuit to be placed in the pocket.

### BACKGROUND OF THE INVENTION

### 1. Field of the Invention

The present invention relates to a tray for substrates of semiconductor integrated circuits such as ICs, and more specifically, the present invention relates to a tray that is suitable for accommodating substantially large-size semiconductor integrated circuits (including semiconductor packages) which have multiple terminals on the bottom face thereof.

### 2. Description of Related Art

A tray for semiconductor integrated circuits (hereinafter also referred to as just “a tray”) is provided with one or a plurality of pockets to accommodate substrates of semiconductor integrated circuits. In addition, a tray for semiconductor integrated circuits is provided with supporting steps that extend horizontally along a pocket of the tray so that the supporting steps support a semiconductor integrated circuit and prevent the inner bottom surface of the pocket from contacting terminals on the bottom face of the semiconductor integrated circuit even if a grid array type (such as PGA-type, BGA-type and so forth) semiconductor integrated circuit is placed in the pocket.

A tray that is pursuant to JEDEC (Electron Device Engineering Council) standard has horizontal and vertical dimensions ([longitudinal size]×[lateral size]) of [315.0 mm-322.6 mm (approx. 12.4 in-12.7 in.)]×[135.9 mm (approx. 5.35 in.)] and can be manipulated through conventional automated machinery for JEDEC standard trays.

However, some substrates of large-size semiconductor integrated circuits may have some deformation caused by erroneous manufacture. Alternatively, when a substrate of a semiconductor integrated circuit happens to be deflected fortuitously, terminals on the bottom face of the semiconductor integrated circuit may contact the inner bottom surface of a pocket of the tray.

Japanese Patent Application Publication No. 2022-142375 discloses a recess on the inner bottom surface of a pocket of a tray, the recess having a flat surface which is approximately analogous to the bottom surface of a semiconductor integrated circuit and having a longer depth than a height of a terminal provided on the bottom face of a semiconductor integrated circuit.

When a tray for large-size semiconductor integrated circuits which is as large as the upper limit of the size of JEDEC standard happens to be deflected, the inner bottom surface of a pocket on the tray may contact terminals on the bottom face of a semiconductor integrated circuit which is to be placed in the pocket. In addition, it has been difficult for conventional automated machinery for JEDEC standard trays to manipulate a tray for large-size semiconductor integrated circuits having horizontal and vertical dimensions of 120×120 mm (approx. 4.72×4.72 in.) or larger in planar view.

### SUMMARY OF THE INVENTION

A tray for large-size semiconductor integrated circuits that comprises one or a plurality of pockets for accommodating large-size semiconductor integrated circuits is provided. A rounded recess having a circular outline is formed on the inner bottom surface of each of the pockets.

In one embodiment, the circular outline is generally concentric with the center of each of the pockets.

In one embodiment, a rounded recess having a circular outline is formed on the opposite side of the inner bottom surface of each of the pockets.

In one embodiment, the circular outline on the opposite side is generally concentric with the center of each of the pockets.

In one embodiment, the rounded recess is comprised of a spherical dome having a predetermined radius of curvature.

In one embodiment, the tray has protruding portions that extend laterally from longitudinal side walls of the tray.

In one embodiment, each of the protruding portions has a generally rectangular shape.

In another embodiment, each of the protruding portions has a generally trapezoidal shape.

In still another embodiment, each of the protruding portions has a generally arcuate shape.

In one embodiment, the protruding portions are arranged at positions which are predetermined distance away from the longitudinal side ends of the tray.

### BRIEF DESCRIPTION OF THE DRAWINGS

FIG. 1 is a plan view illustrating an example of a tray for semiconductor integrated circuits according to the present invention.

FIG. 2 is an enlarged plan view of a pocket of the tray for semiconductor integrated circuits in FIG. 1.

FIG. 3 illustrates a tray with a rounded recess formed on the inner bottom surface of a pocket of the tray.

FIG. 4 illustrates a tray with a rounded recess formed on the opposite side of the inner bottom surface of a pocket of the tray.

FIG. 5 illustrates a tray with rounded recesses formed on the inner bottom surface and the opposite side of the inner bottom surface of a pocket of the tray.

FIG. 6 is a cross-sectional view illustrating an arched, rounded recess formed on the inner bottom surface of a pocket of the tray.

FIG. 7 is a cross-sectional view illustrating an arched, rounded recess formed on the opposite side of the inner bottom surface of a pocket of the tray.

FIG. 8 is a cross-sectional view illustrating arched, rounded recesses formed on the inner bottom surface and the opposite side of the inner bottom surface of a pocket of the tray.

FIG. 9 illustrates a tray provided with a protruding portion having a rectangular shape.

FIG. 10 illustrates a tray provided with a protruding portion having a trapezoidal shape.

FIG. 11 illustrates a tray provided with a protruding portion having an arcuate shape.

### DETAILED DESCRIPTION OF THE INVENTION

Hereinafter, an example tray for large-size semiconductor integrated circuits according to the present invention will be described in detail based on embodiments which are illustrated in the attached drawings.

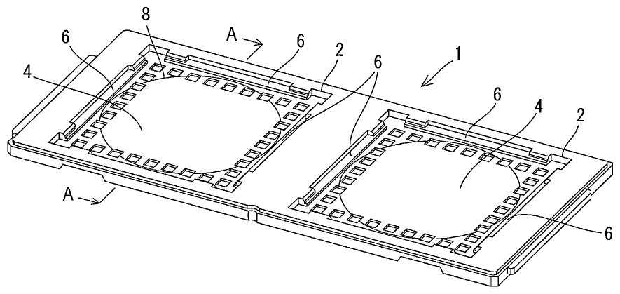

FIG. 1 is a perspective view of an example tray 1 for semiconductor integrated circuits. The upper surface of a tray 1 is provided with one or a plurality of pockets 2 depending on the figuration and size of semiconductor integrated circuits which are to be placed in pockets 2 of the tray 1. In addition, a pocket 2 is provided with supporting steps 6 that extend horizontally along the inner side walls of the pocket 2 for supporting edges of a semiconductor integrated circuit and prevent the inner bottom surface 4 of the pocket 2 from contacting terminals 7 on the bottom face 4 of the semiconductor integrated circuit.

As illustrated in FIG. 1, a rounded recess 10 having a circular outline 8 is formed on the inner bottom surface of each of two pockets 2 on the upper surface of the tray 1.

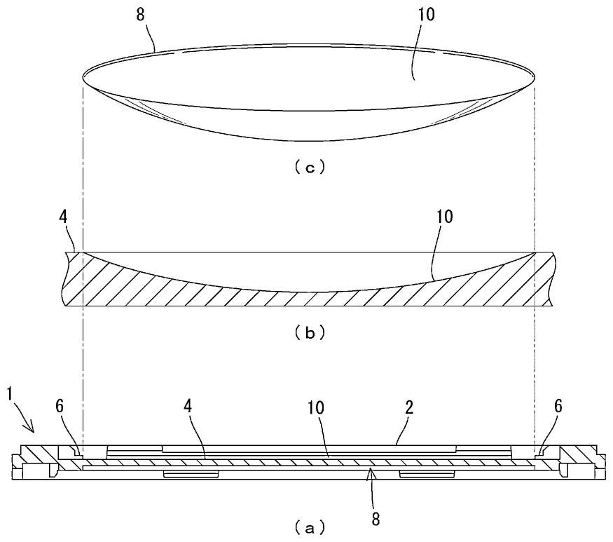

FIG. 2(a) is a sectional view taken along line A-A in FIG. 1.

FIG. 2(b) illustrates a tray 1 so exaggeratingly as to clarify a rounded recess 10 although a real rounded recess 10 is too slightly rounded for the naked eye to see. As illustrated in FIG. 2(b), a rounded recess 10 may be formed on the inner bottom surface 4 of a pocket 2 of the tray 1.

FIG. 2(c) is a perspective view showing that the rounded recess 10 is comprised of a turned spherical dome (a sphere segment taken along the inner bottom surface 4). FIG. 2(c) exaggeratingly illustrates a tray 1 so that the rounded surface of a spherical dome can be seen clearly. As illustrated, the rounded recess 10 formed on the inner bottom surface 4 of a pocket 2 prevents the inner bottom surface 4 from contacting terminals on the bottom face (especially terminals around the center of the substrate) of a semiconductor integrated circuit which is to be placed in the pocket 2. The dashed-dotted lines across FIGS. 2(a)-(c) indicate mutually corresponding points.

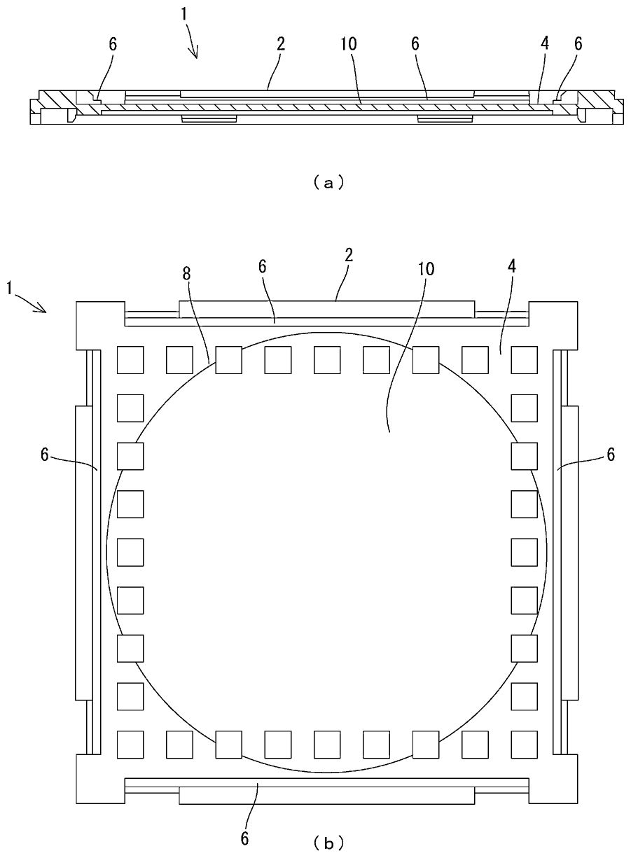

FIG. 3 illustrates an example tray 1. FIG. 3(a) is a cross-sectional view taken along line A-A in FIG. 1. FIG. 3(b) illustrates a rounded recess 10 formed on the inner bottom surface 4 of a pocket 2 of the tray 1. FIG. 3(b) further illustrates a circular outline 8 of the rounded recess 10 in the pocket 2 wherein the circular outline 8 is generally concentric with the center of the pocket 2 (i.e. two diagonal lines to the opposite corners of the pocket 2 intersect each other at the center of the circular outline). In one embodiment, a circular outline 8 has a radius as illustrated while in another embodiment, a circular outline 8 may have a different radius. In some embodiments, the rounded recess 10 is comprised of a spherical dome (a spherical segment taken along the inner bottom surface 4) having a predetermined radius of curvature within a range from 1000 mm to 5000 mm (from approx. 39.37 in. to approx. 196.9 in.). For example, the predetermined radius of curvature is 3000 mm (approx. 118.1 in.).

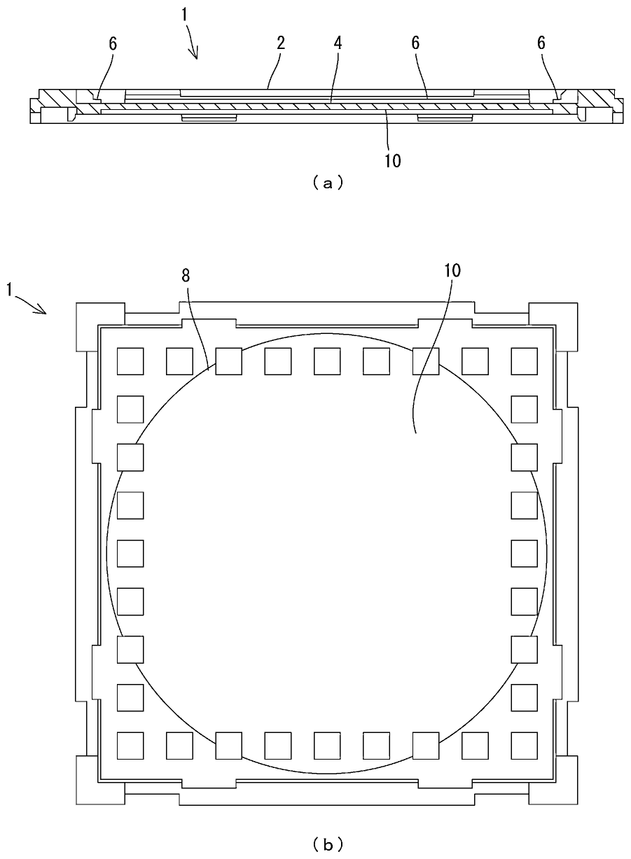

FIG. 4 illustrates another example tray 1. FIG. 4(a) is a cross-sectional view taken along line A-A in FIG. 1. As illustrated in FIG. 4(b), a rounded recess 10 is formed on the opposite side of the inner bottom surface of a pocket 2 of the tray 1. FIG. 4(b) further illustrates a circular outline 8 of the rounded recess 10 wherein the circular outline 8 is generally concentric with the center of the pocket 2. In some embodiments, the rounded recess 10 is comprised of a spherical dome (a spherical segment taken along the lower side of the tray 1) having a predetermined radius of curvature.

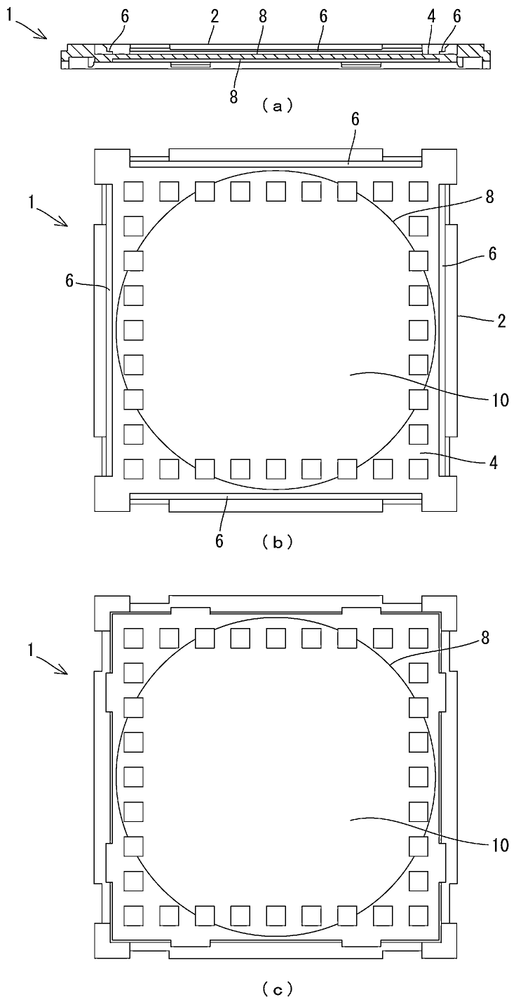

FIG. 5 illustrates still another example tray 1. FIG. 5(a) is a cross-sectional view taken along line A-A in FIG. 1. In this example, rounded recesses 10 are formed on the upper and lower surfaces of the tray 1 as illustrated in FIGS. 5(b)-(c). FIG. 5(b) shows a rounded recess 10 formed on the inner bottom surface 4 of a pocket 2 of the tray 1. FIG. 5(c) shows a rounded recess 10 formed on the opposite side of the inner bottom surface 4 of the pocket 2. FIGS. 5(b)-(c) further show circular outlines 8 of the rounded recesses 10 which are generally concentric with the center of the pocket 2. With such a structure, the tray 1 can resist a force in the bending direction of the tray 1 in spite of its thinness and avoid deformation (warpage, deflection and so forth) of the substrate of the tray 1 when large-size semiconductor integrated circuits 6 are packed in the tray 1.

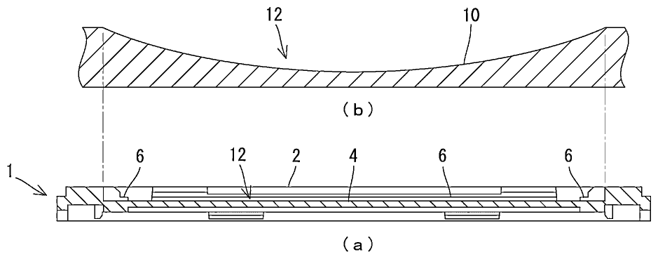

FIG. 6 illustrates a first embodiment of the present invention. FIG. 6(a) is a cross-sectional view taken along line A-A in FIG. 1. FIG. 6(b) is a cross-sectional view exaggeratingly illustrating an arched, rounded recess 10 formed on the inner bottom surface 4 of a pocket 2 of the tray 1. Such a rounded recess 10 formed on the inner bottom surface 4 of a pocket 2 prevents the inner bottom surface 4 from contacting terminals on the bottom face (especially terminals around the center of the substrate) of a semiconductor integrated circuit which is to be placed in the pocket 2.

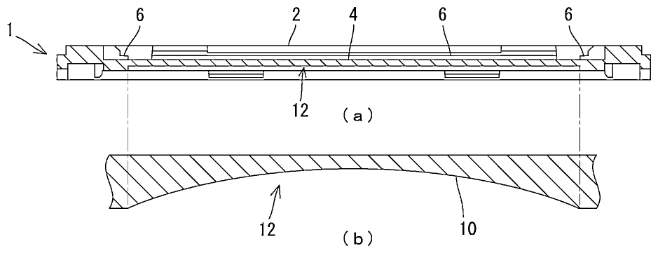

FIG. 7 illustrates a second embodiment of the present invention. FIG. 7(a) is a cross-sectional view taken along line A-A in FIG. 1. FIG. 7(b) is a cross-sectional view 12 exaggeratingly illustrating an arched, rounded recess 10 on the opposite side of the inner bottom surface 4 of a pocket 2 of a tray 1. In spite of its thinness, the tray 1 is rigid and hard to break because the weight of a substrate of semiconductor integrated circuit will be received by the bridged structure of a rounded recess 10 on the lower side of the tray 1.

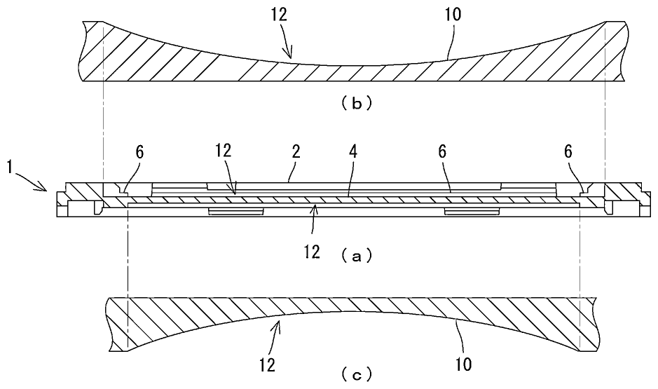

FIG. 8 illustrates a third embodiment of the present invention. FIG. 8(a) is a cross-sectional view 12 taken along line A-A in FIG. 1. FIG. 8(b) is a cross-sectional view 12 illustrating an arched, rounded recess 10 on the inner bottom surface 4 of a pocket 2 of the tray 1. FIG. 8(c) is a cross-sectional view 12 illustrating an arched, rounded recess 10 on the opposite side of the inner bottom surface 4 of the pocket 2. FIGS. 8(b)-(c) illustrate the tray 1 exaggeratingly so that a bridged structure (an arch construction) can be seen clearly.

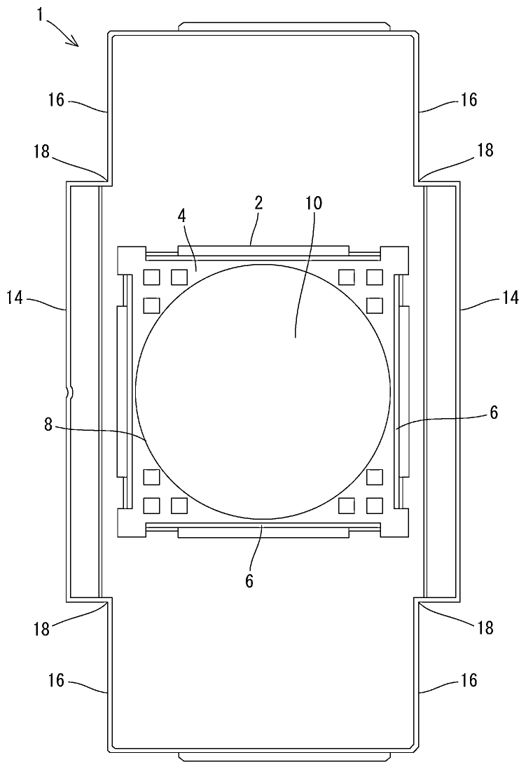

The tray 1 illustrated in FIGS. 9-11 has protruding portions 14. The protruding portions 14 may enable a pocket 2 of the tray 1 to accommodate a semiconductor integrated circuit having horizontal and vertical dimensions of 120×120 mm (approx. 4.72×4.72 in.) or larger in planar view. The figuration and dimensions of the protruding portions 14 may be designed depending on the size, weight and so forth of semiconductor integrated circuits which are to be placed in pockets 2 of the tray 1. The protruding portions 14 may extend laterally from the longitudinal side walls 16 of the tray 1.

FIG. 9 illustrates protruding portions 14 in a first embodiment, each of which has a generally rectangular shape. FIG. 9 further illustrates positions 18 beyond which the protruding portions 14 extend laterally from the longitudinal side walls 16 of the tray 1, which makes a cross-like figure as illustrated. Those positions 18 are predetermined distance away from the longitudinal side ends (i.e. corner edges) of the tray 1. The positions 18 should be from 20 to 70 mm (approx. from 0.79 to 2.76 in.) away from the longitudinal side ends of the tray 1, which makes possible for conventional automated machinery for JEDEC standard trays to manipulate the tray 1 with those protruding portions 14 though the tray 1 with those protruding portions 14 is, technically speaking, not pursuant to JEDEC standard.

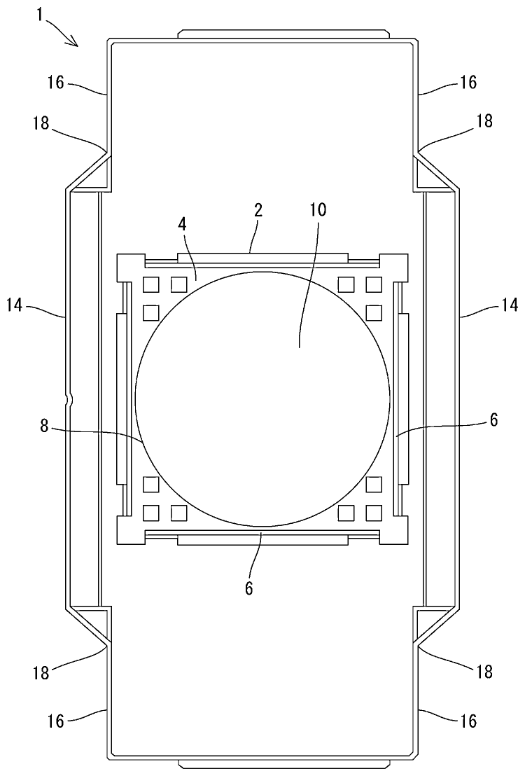

FIG. 10 illustrates protruding portions 14 in a second embodiment, each of which has a generally trapezoidal shape.

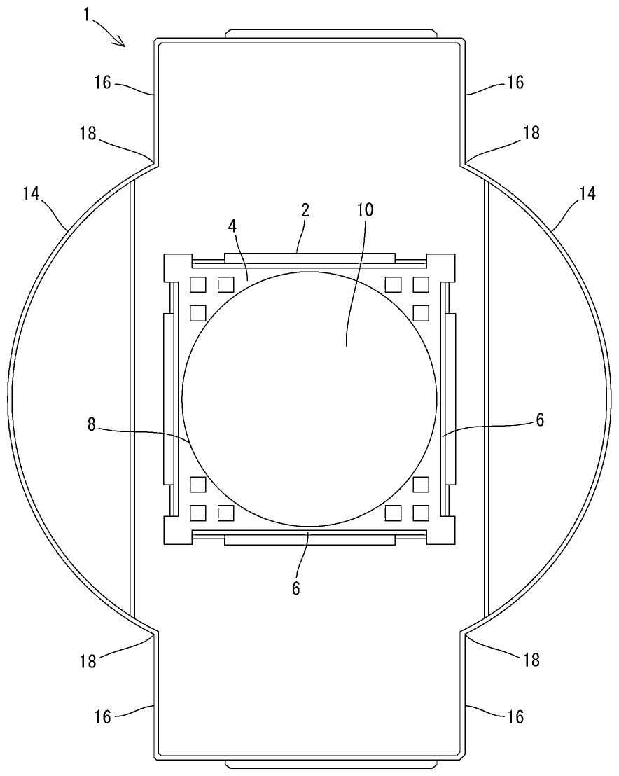

FIG. 11 illustrates protruding portions 14 in a third embodiment, each of which has a generally arcuate shape outlined by an arc (whose central angle is less than 180 degrees) and a subtense that connects two ends of the arc.

### REFERENCE SIGNS LIST

1 tray
2 pocket
4 inner bottom surface
6 supporting step
8 circular outline
10 rounded recess
12 arched cross-section
14 protruding portion
16 longitudinal side wall
18 position predetermined distance away from a corner

1. A tray for large-size semiconductor integrated circuits that comprises:
one or a plurality of pockets for accommodating large-size semiconductor integrated circuits;
wherein a rounded recess having a circular outline is formed on the inner bottom surface of each of the pockets.

2. The tray for large-size semiconductor integrated circuits according to claim 1,
wherein the circular outline is generally concentric with the center of each of the pockets.

3. The tray for large-size semiconductor integrated circuits according to claim 2,
wherein a rounded recess having a circular outline is formed on the opposite side of the inner bottom surface of each of the pockets.

4. The tray for large-size semiconductor integrated circuits according to claim 3,
wherein the circular outline on the opposite side is generally concentric with the center of each of the pockets.

5. The tray for large-size semiconductor integrated circuits according to claim 1,
wherein the rounded recess is comprised of a spherical dome having a predetermined radius of curvature.

6. The tray for large-size semiconductor integrated circuits according to claim 1,
wherein the tray has protruding portions that extend laterally from longitudinal side walls of the tray.

7. The tray for large-size semiconductor integrated circuits according to claim 6,
wherein each of the protruding portions has a generally rectangular shape.

8. The tray for large-size semiconductor integrated circuits according to claim 6,
wherein each of the protruding portions has a generally trapezoidal shape.

9. The tray for large-size semiconductor integrated circuits according to claim 6,
wherein each of the protruding portions has a generally arcuate shape.

10. The tray for large-size semiconductor integrated circuits according to claim 6,
wherein each of the protruding portions has a generally rectangular shape, a generally trapezoidal shape, or a generally arcuate shape; and
wherein the protruding portions are arranged at positions which are predetermined distance away from the longitudinal side ends of the tray.
